(19) United States
(12) Patent Application Publication
(10) Pub. No.: US 2003/0066680 A1
(43) Pub. Date: Apr. 10, 2003

(54) Terminal electrode of thin-film device with improved mounting strength, manufacturing method for the same, and thin-film magnetic head

(75) Inventors: Katsuya Kikuiri, Niigata-ken (JP); Takashi Takabatake, Niigata-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 10/256,542

(22) Filed: Sep. 26, 2002

(30) Foreign Application Priority Data
Oct. 4, 2001 (JP) 2001-309163

(51) Int. Cl. H05K 1/09

(52) U.S. Cl. 174/257

(57) ABSTRACT

A terminal electrode provided on a lead joint of a thin-film device fabricated by a thin-film technology. The terminal electrode is constituted by an upper pad and a lower pad, the lower pad being formed into a pillar-like shape protuberantly projecting from the lead joint. The upper pad, which is wider than the lower pad, is formed on the lower pad such that the center thereof is aligned with the center of the lower pad. This arrangement provides the terminal electrode that allows a higher-density insulating layer free of defects, such as voids, to be formed around the terminal electrode, leading to an improved mounting strength of the terminal electrode.

### BACKGROUND OF THE INVENTION

1. Field of the Invention

The present invention relates to a terminal electrode provided on a lead wire joint portion of a thin-film device, such as a thin-film magnetic head or an MR sensor, a method for manufacturing the same, and a thin-film magnetic head.

2. Description of the Related Art

A thin-film magnetic head has a lead portion or a lead wire for connecting a thin-film coil wound around a core to an external circuit. A terminal electrode for terminal connection is formed on a distal end of the lead wire.

Conventionally, this type of terminal electrode frequently has a structure in which a pillar-shaped terminal electrode is formed on the distal end of a lead wire formed on a substrate, and an insulating layer covers the terminal electrode.

A terminal electrode 100 having an umbrella-shaped section (FIG. 14), which is different from the pillar-shaped terminal electrode, is sometimes used. To fabricate the terminal electrode 100 shown in FIG. 14, in a structure where, for example, a lead portion or lead wire 102 is formed on a substrate 101, a resist is applied to the substrate 101 and the lead wire 102, a contact hole 104 is formed in a part of a resist 103 by photolithography, as shown in FIG. 12, then a plating conductive material is deposited to fill the contact hole 104 by plating so as to form the pillar-shaped terminal electrode 100.

In this case, to form a pillar-shaped electrode portion 100A by filling the contact hole 104 with a plating material, the plating process is continued to cause a part of the plating material to overflow from the contact hole 104 thereby to produce an electrode portion 100B having an umbrella-shaped section. This is how the terminal electrode 100 can be formed to have the umbrella-shaped section, as shown in FIG. 13 and FIG. 14.

Then, the resist 103 is removed, leaving the terminal electrode 100. Subsequently, an insulating layer made of alumina or the like is deposited around the terminal electrode 100 having the umbrella-shaped section by using a film forming process, such as sputtering. This makes it possible to obtain the terminal electrode structure wherein an insulating layer 106 wraps the terminal electrode 100 having the umbrella-shaped section, as shown in FIG. 14. A gold electrode layer 105 is deposited on the terminal electrode 100 to complete the structure of the terminal electrode with the section illustrated in FIG. 14.

In the terminal electrode 100 having the structure shown in FIG. 14, the lead wire 102 is formed to have a small width, e.g., a few dozen μm, as the size of a thin-film magnetic device or the like is increasingly reduced. This means that the electrode portion 100A has to be formed to have a small sectional width, while the terminal electrode 100 is required to have a joint surface area of a certain size (e.g., 100×100 μm) in order to allow wire bonding for connection with an external circuit. It is logical, therefore, that the electrode has the umbrella-shaped section.

In the terminal electrode 100 having the structure illustrated in FIG. 14, the portion of the insulating layer 106 located below the umbrella-shaped electrode portion 100B is apt to have a defect, such as a void, leading to a danger in that the connection strength of the terminal electrode 100 is deteriorated in a wire bonding process. This defect is considered attributable to the following cause. When the umbrella-shaped electrode portion 100B is formed by sputtering or by other means for forming a thin film, sputter particles are deposited from above the electrode portion 100B to form the insulating layer. Hence, the umbrella-shaped electrode portion 100B prevents the sputter particles from being deposited onto the bottom side thereof. As a result, the deposition density of the sputter particles reduces.

The problem described above is particularly marked in a thin-film magnetic head for video equipment, such as a VTR, or a thin-film magnetic head for a data storage magnetic recording apparatus because of the following reason. After a thin-film magnetic head is completed, a circuit for inspection is wire-bonded to a terminal electrode of the thin-film magnetic head, then the bonding wire for the inspection is removed once after the inspection. To install the thin-film magnetic head in final equipment, such as video equipment or a magnetic recording apparatus, second wiring bonding is carried out. There has been a problem in that, when the inspection circuit wire-bonded to the terminal electrode is removed, the terminal electrode may come off-from the portion of the insulating layer under the umbrella-shaped terminal electrode.

According to a possible alternative, the terminal electrode 100 having the umbrella-shaped section shown in FIG. 13 is formed, the resist 103 is removed, the insulating layer is deposited up to the upper edge of the electrode portion 100A, only the umbrella-shaped electrode portion 100B is removed by polishing so as to leave the electrode portion 100A, and a separate upper electrode is formed on the electrode portion 100A to produce a pillar-shaped terminal electrode. According to this method, however, the porous, low-density portion of the insulating layer that has been formed on the bottom side of the umbrella-shaped electrode portion 100B undesirably remains. Hence, the problem of the defects in the area around the terminal electrode is not solved.

### SUMMARY OF THE INVENTION

Accordingly, the present invention has been made with a view toward solving the problem described above, and it is an object of the present invention to provide a terminal electrode featuring improved mounting strength of the terminal electrode by restraining the danger of defects, such as voids, in an insulating layer around the terminal electrode so as to obtain a high-density insulating layer.

It is another object of the present invention to provide a terminal electrode that features improved mounting strength of the terminal electrode by eliminating the danger of defects, such as voids, in an insulating layer around the terminal electrode so as to obtain a high-density insulating layer, and also features a structure that permits easier wire bonding.

It is yet another object of the present invention to provide a method that makes it possible to fabricate the terminal electrode of the structure having the features described above.

To these ends, according to a first aspect, there is provided a terminal electrode of a thin-film device, the terminal electrode being provided on a lead joint portion of a thin-film device fabricated by a thin-film technology, including an upper pad and a lower pad, wherein the lower pad is shaped like a pillar projecting from the lead joint portion, and the upper pad, which is wider than the lower pad, is formed on the lower pad such that the center thereof is aligned with the center of the lower pad.

The upper pad, which is formed to be larger than the lower pad, ensures reliable connection with a fine wire on the lower pad, and permits a sufficiently large joint area to be secured for wire bonding even in a terminal electrode for a wiring structure adapted to a microminiature thin-film device. This arrangement allows perfect, firm electrical connection to be achieved.

Furthermore, since the upper pad is made larger than the lower pad, and the centers of the upper pad and the lower pad are aligned, reliable connection can be accomplished at right above the lower pad when wire bonding is carried out through the intermediary of the upper pad. In addition, the presence of the larger upper pad allows a sufficiently large area to be secured for the joint portion of the terminal electrode.

Preferably, a lower insulating layer is formed around the lower pad such that it surrounds the lower pad and its front surface is flush with the upper end surface of the lower pad.

The upper end surface of the lower pad and the front surface of the lower insulating layer surrounding the lower pad are flush with each other, so that the upper pad formed on the lower pad and the front surface of the lower insulating layer can be securely connected to the lower pad.

Preferably, an upper insulating layer is formed around the upper pad such that it surrounds the upper pad and its front surface is flush with the upper end surface of the upper pad.

Preferably, an electrode pad made of a precious metal is formed on the upper pad such that it covers the upper end surface of the upper pad and is electrically connected to the upper pad, and covers the upper end surface of the upper pad and adheres to the front surface of the upper insulating layer.

The addition of the electrode pad, which is larger than the upper pad, makes it possible to secure a sufficiently large joint area for wire bonding. Moreover, the electrode pad made of a precious metal is highly resistant to corrosion, minimizing the chance of causing the upper pad to corrode.

According to a second aspect of the present invention, there is provided a magnetic head equipped with one of the terminal electrodes described above. This arrangement provides a magnetic head that has the various features of the terminal electrodes and exhibits high connection strength of the mounting portion of the terminal electrode.

According to a third aspect of the present invention, there is provided a manufacturing method for a terminal electrode formed of a lower pad and an upper pad and placed on a lead formed on a substrate, the manufacturing method including a step of applying a resist onto the substrate and the lead, a step of forming a contact hole reaching the lead in the resist, a step of forming a lower pad made of a conductive material to fill the contact hole, a step of removing the resist after forming the lower pad, a step of forming an insulating layer around the lower pad, a step of planarizing the upper surface of the insulating layer and the upper surface of the lower pad, and a step of forming an upper pad on the lower pad.

The manufacturing method allows a terminal electrode to be obtained that is provided with the lower pad and the upper pad. Furthermore, the planarized lower pad and lower insulating layer permit the upper pad to be connected onto the lower pad.

Preferably, the lower pad is formed by filling the contact hole with a conductive material such that the conductive material is not overflown out of the contact hole, then the lower pad and the lower insulating layer around the lower pad are planarized.

Preferably, the lower pad is formed such that the conductive material filling the contact hole is not overflown out of the contact hole so as to form the lower pad into a pillar-like shape rather than forming it into an umbrella-like shape. Hence, when depositing the lower insulating layer around the lower pad by a film forming process, a dense lower insulating layer can be produced without causing defects, such as voids, to take place in the lower insulating layer surrounding the lower pad.

Preferably, after a resist is applied to the planarized upper surfaces of the lower pad and the lower insulating layer, a second contact hole, which is wider than the lower pad, is formed in the resist at a position coaxial with the lower pad. Then, the second contact hole is filled with a conductive material such that it does not overflow out of the second contact hole, thereby forming the upper pad.

The conductive material is charged in the contact hole so that it does not overflow out of the contact hole, thereby forming the upper pad. This allows the upper pad to be formed into a pillar-like shape rather than the umbrella-like shape. Hence, when an upper insulating layer is deposited around the upper pad, a dense upper insulating layer can be produced without causing voids or other similar defects to take place in the upper insulating layer surrounding the upper pad.

Preferably, after the upper pad is formed, a second insulating layer is formed to surround the upper pad, and an electrode pad made of a precious metal is formed on the upper pad and the second insulating layer.

Preferably, the electrode pad is formed such that it covers the upper surface of the upper pad, is electrically connected to the upper pad, and covers a part of the insulating layer around the upper pad.

Thus, it is possible to provide a terminal structure in which the upper pad is highly resistant to corrosion.

### BRIEF DESCRIPTION OF THE DRAWINGS

FIG. 1 is a sectional view showing a structure of a terminal electrode in accordance with the present invention;

FIG. 2 is a diagram showing a process for manufacturing the terminal electrode shown in FIG. 1, this diagram being a sectional view illustrating a resist layer deposited on a substrate provided with a lead wire;

FIG. 3 is a diagram showing a process for manufacturing the terminal electrode shown in FIG. 1, this diagram being a sectional view illustrating a state wherein a contact hole has been formed in the resist layer;

FIG. 4 is a diagram showing a process for manufacturing the terminal electrode shown in FIG. 1, this diagram being a sectional view illustrating a state wherein a lower pad and a first insulating layer have been added;

FIG. 5 is a diagram showing a process for manufacturing the terminal electrode shown in FIG. 1, this diagram being a sectional view illustrating a state wherein a second resist layer has been formed on the first insulating layer;

FIG. 6 is a diagram showing a process for manufacturing the terminal electrode shown in FIG. 1, this diagram being a sectional view illustrating a state wherein a contact hole has been formed in the second resist layer;

FIG. 7 is a diagram showing a process for manufacturing the terminal electrode shown in FIG. 1, this diagram being a sectional view illustrating a state wherein an upper pad has been formed in the contact hole;

FIG. 8 is a diagram showing a process for manufacturing the terminal electrode shown in FIG. 1, this diagram being a sectional view illustrating a state wherein the resist layer around the upper pad has been removed;

FIG. 9 is a perspective schematic view showing an example of a thin-film magnetic head to which the structure of the terminal electrode in accordance with the present invention has been applied;

FIG. 10 is a partial sectional perspective schematic view showing the example of the thin-film magnetic head to which the structure of the terminal electrode in accordance with the present invention has been applied;

FIG. 11 is a partial sectional view illustrating the example of the thin-film magnetic head to which the structure of the terminal electrode in accordance with the present invention has been applied;

FIG. 12 is a diagram showing a process for manufacturing an example of a conventional terminal electrode, this diagram being a sectional view illustrating a state wherein a resist layer and a contact hole have been formed on a substrate;

FIG. 13 is a diagram showing the process for manufacturing the example of the conventional terminal electrode, this diagram being a sectional view illustrating a state wherein an umbrella-shaped terminal electrode has been formed in a contact hole; and

FIG. 14 is a diagram showing the process for manufacturing the example of the conventional terminal electrode, this diagram being a sectional view illustrating a state wherein an electrode pad has been formed on the terminal electrode.

### DESCRIPTION OF THE PREFERRED EMBODIMENTS

A first embodiment in accordance with the present invention will now be described with reference to the accompanying drawings. It is obvious, however, that the present invention is not restricted to the embodiments discussed below.

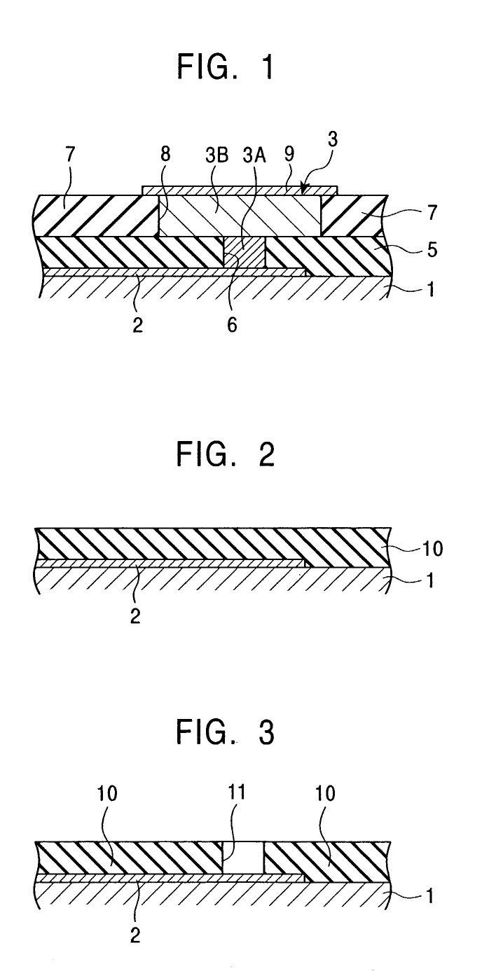

FIG. 1 is a sectional view showing a terminal electrode 3 connected to a part of a lead wire or lead portion 2 formed on a substrate 1. The terminal electrode 3 is constituted by a pillar-shaped lower pad 3A protuberantly formed on an end of the lead wire 2 and an upper pad 3B formed on the lower pad 3A continuously therefrom. To be more specific, a first insulating layer 5 is formed to cover the upper surface of the substrate 1 and the lead wire 2, and a contact hole 6 is formed in the first insulating layer 5 such that it is positioned on a part of the lead wire 2. The pillar-shaped lower pad 3A is formed to fill the contact hole 6 thereby to be connected to the lead wire 2. the upper surface of the lower pad 3A and the upper surface of the first insulating layer 5 are formed to be flush.

An upper pad 3B, which is wider than the lower pad 3A, is formed on the lower pad 3A continuously from the lower pad 3A. To be more specific, a second insulating layer 7 is deposited to cover the upper surface of the first insulating layer 5, and a contact hole 8, which is wider than the lower pad 3A, is formed in the second insulating layer 7 and on the lower pad 3A. The upper pad 3B is formed to fill the contact hole 8 and to be connected to the lower pad 3A.

The lower pad 3A and the upper pad 3B are both conductors formed of a good conductive metal material, such as Cu, Ni, Ag, or Au. The cross-sections of these pads 3A and 3B may have a round, rectangular, or other shape. This means that the lateral and/or longitudinal width of the cross section of the upper pad 3B is larger than that of the lower pad 3A. In other words, if both pads are pillar-shaped, then the upper pad 3B has a larger diameter than the lower pad 3A.

Furthermore, the center of the lower pad 3A and the center of the upper pad 3B are aligned at the same central axis; therefore, the lower pad 3A is located under the central portion of the upper pad 3B. In this embodiment, the lower pad 3A is formed to have a width of about 30 μm to about 150 μm to match the width of the lead wire 2, while the upper pad 3B is formed to have a width of about 150 μm to about 400 μm to assure sufficient connection for wire bonding or the like.

An example of the manufacturing method for the terminal electrode 3 shown in FIG. 1 will now be described.

To fabricate the terminal electrode 3, the substrate 1 with the lead wire 2 formed on its upper surface is prepared first, then a first resist layer 10 is deposited on the substrate 1 to cover the upper surface of the substrate 1 and the lead wire 2. For the first resist layer 10, a commercially available resist material, a dry film, or the like may be used. The first resist layer 10 may be deposited to a thickness of about 5 μm to about 50 μm. The deposited first resist layer 10 may be hardened by pre-baking, as necessary.

Then, the first resist layer 10 is exposed for development so as to form a contact hole 11 that has, for example, a round section and reaches a part of the lead wire 2, as shown in FIG. 3. Subsequently, the contact hole 11 is filled with a conductive material, such as Ni or Cu, by plating to form the pillar-shaped lower pad 3A. The plating is to be terminated the moment the contact hole 11 has been filled up with the conductive material. In this case, a considerable overflow of the conductive material out of the contact hole 11 should be avoided, because it would form the lower pad into an umbrella-shaped electrode. A slight overflow of the conductive material should not cause a problem.

Upon completion of the plating, the first resist layer 10 is removed, then a first insulating layer 13 made of an insulating material, such as alumina (Al₂O₃), is deposited on the substrate by a film forming method, e.g., sputtering. The lower pad 3A is almost columnar rather than having the umbrella-shaped section when depositing the insulating material, thus allowing the sputter particles to be densely deposited when the insulating material is deposited. This makes it possible to obtain the first insulating layer 13 formed of a dense deposited layer free of voids or the like even at around the lower pad 3A.

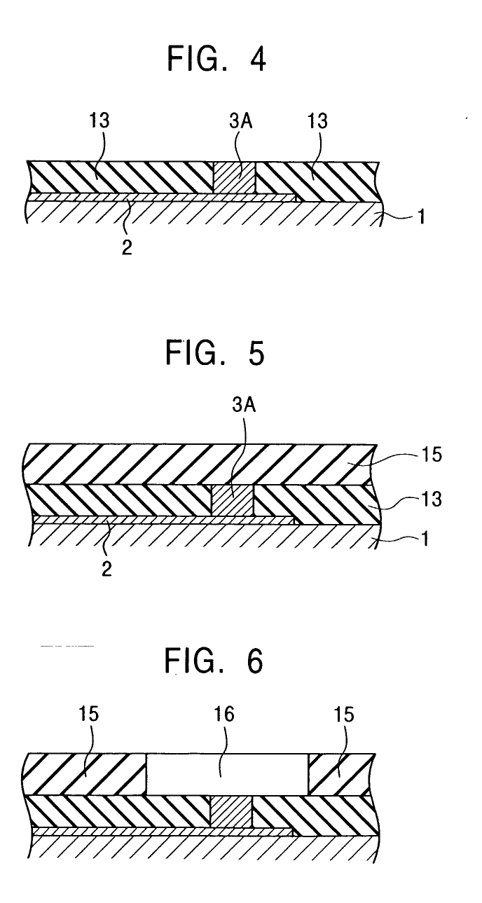

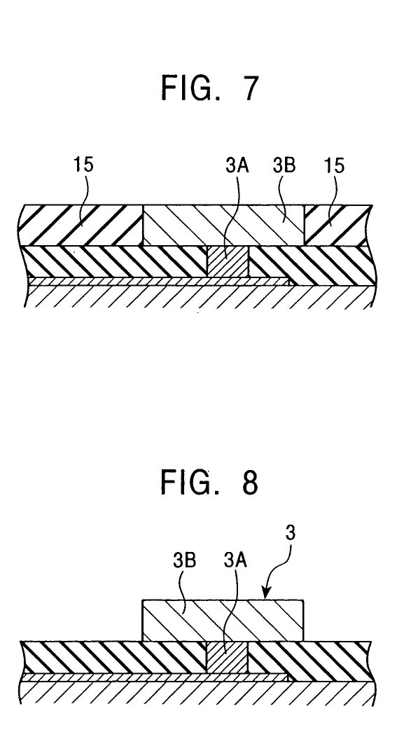

In the next step, the chemical mechanical polishing (CMP) is carried out to accurately planarize the upper surfaces of the lower pad 3A and the first insulating layer 13, as shown in FIG. 4.

Then, a second resist layer 15 is formed on the planarized lower pad 3A and the first insulating layer 13 by the same method as that used for forming the above first resist layer 10. The second resist layer 15 is exposed for development so as to form a contact hole 16 that has, for example, a round section, has a larger diameter than the lower pad 3A, and reaches the lower pad 3A, as shown in FIG. 6.

Subsequently, the contact hole 16 is filled with a conductive material, such as Ni or Cu, by plating to form the upper pad 3B. The plating is to be terminated the moment the contact hole 16 has been filled up with the conductive material. In this case, a considerable overflow of the conductive material out of the contact hole 16 should be avoided, because it would form the upper pad to have an umbrella-shaped section.

Upon completion of the plating, the second resist layer 15 is removed, as illustrated in FIG. 8, then the second insulating layer 7 made of an insulating material, such as alumina (Al₂O₃), is deposited on the substrate by a film forming method, e.g., sputtering. Thus, the terminal electrode 3 shown in FIG. 1 can be obtained. The upper pad 3B has a columnar shape rather than the umbrella-like shape of the conventional one, thus allowing the sputter particles to be densely deposited when the insulating material is deposited. This makes it possible to obtain the second insulating layer 7 formed of a dense deposited layer free of voids or the like even at around the upper pad 3B.

The upper surfaces of the upper pad 3B and the second insulating layer 7 may be polished to planarize them.

Then, an electrode pad 9 is formed on the upper pad 3B by Au plating or precious metal plating or the like. Thus, the terminal electrode 3 having the structure shown in FIG. 1 is obtained.

The structure of the terminal electrode 3 obtained by the manufacturing method described above makes it possible to achieve the dense insulating layer structure in which the first insulating layer 5 surrounding the lower pad 3A is free of defects, such as voids, and also to obtain the terminal electrode 3 having the dense insulating layer structure in which the second insulating layer 7 surrounding the upper pad 3B is free of defects, such as voids. Hence, the terminal electrode 3 surrounded by the dense insulating layers 5 and 7 free of defects, such as voids, as described above permits stronger connection to be achieved. Even if bonding wires are pulled off when wire bonding or a similar operation is repeatedly carried out through the intermediary of the electrode pad 9, it is possible to prevent a problem such as the terminal electrode 3 coming off the insulating layer 5 or 7. In other words, it is possible to provide a terminal electrode 3 featuring an enhanced connection structure that survives repeated wire bonding operations involving the drawing off of bonding wires.

Moreover, the electrode pad 9 is wider than the upper pad 3B, and the upper surface of the upper pad 3B is therefore covered by the electrode pad 9, preventing the upper pad 3B from being exposed. Hence, if the electrode pad 9 is formed of a precious metal, then the corrosion of the upper pad 3B can be prevented. For this reason, the electrode pad 9 is preferably large enough to cover the entire upper pad 3B with a slight allowance.

Thus, the upper pad 3B is larger than the lower pad 3A and the electrode pad 9 is larger than the upper pad 3B, so that a sufficiently large area can be secured for wire bonding, allowing firm connection to be achieved.

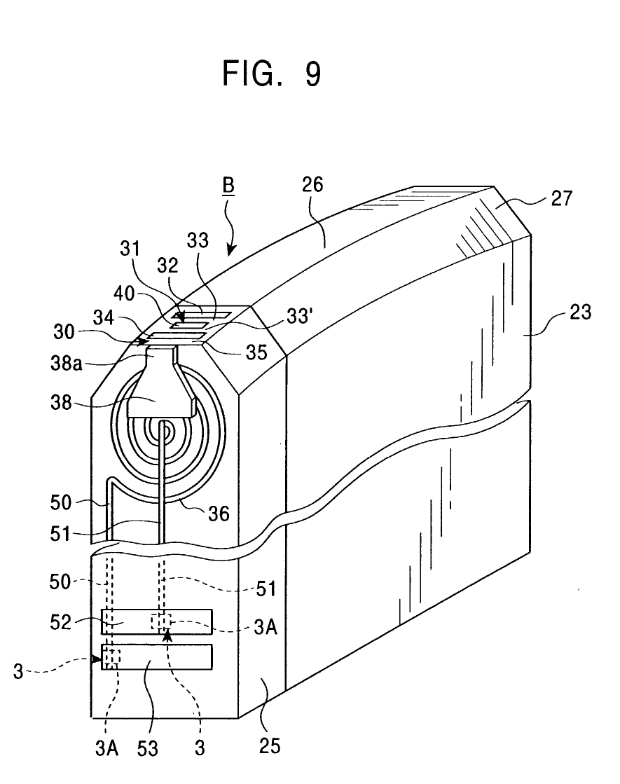

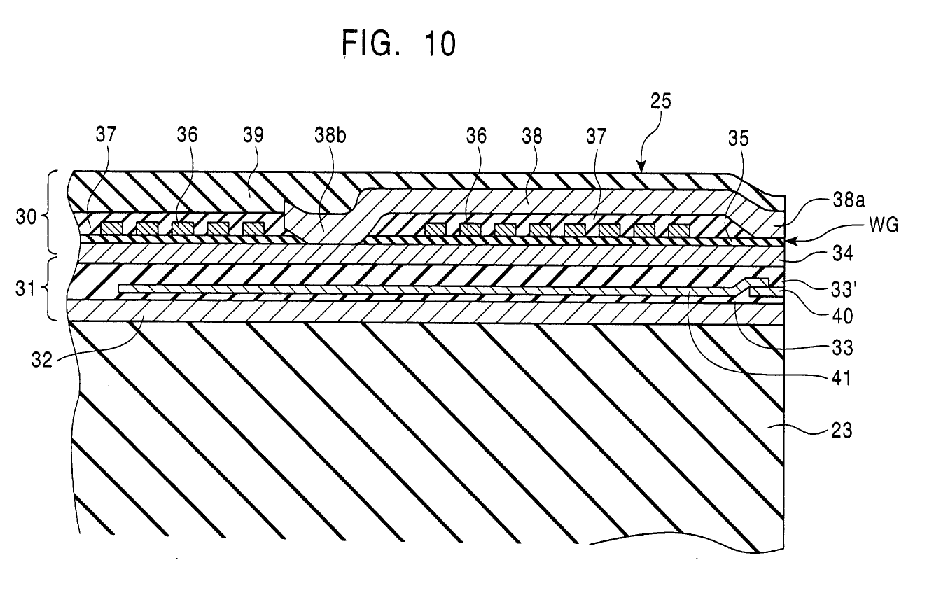

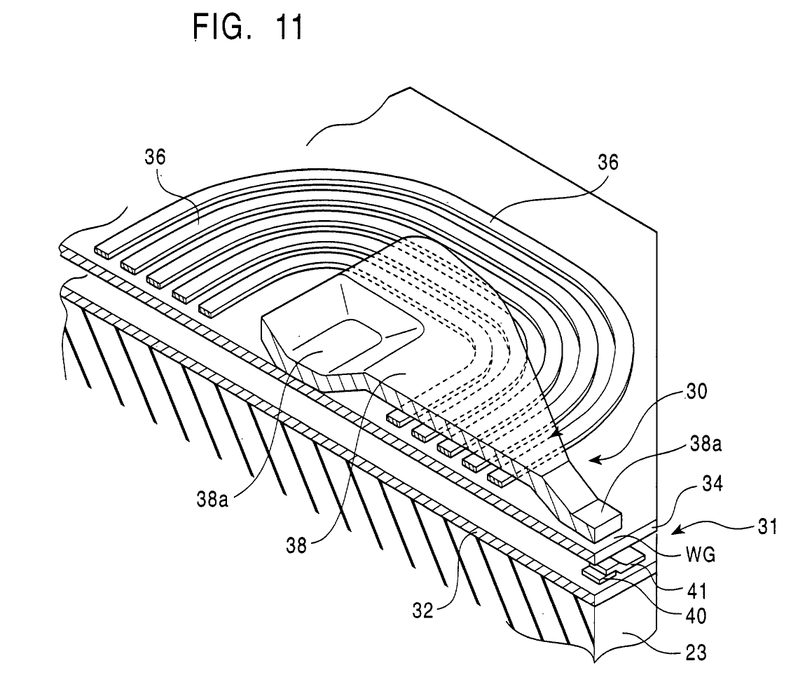

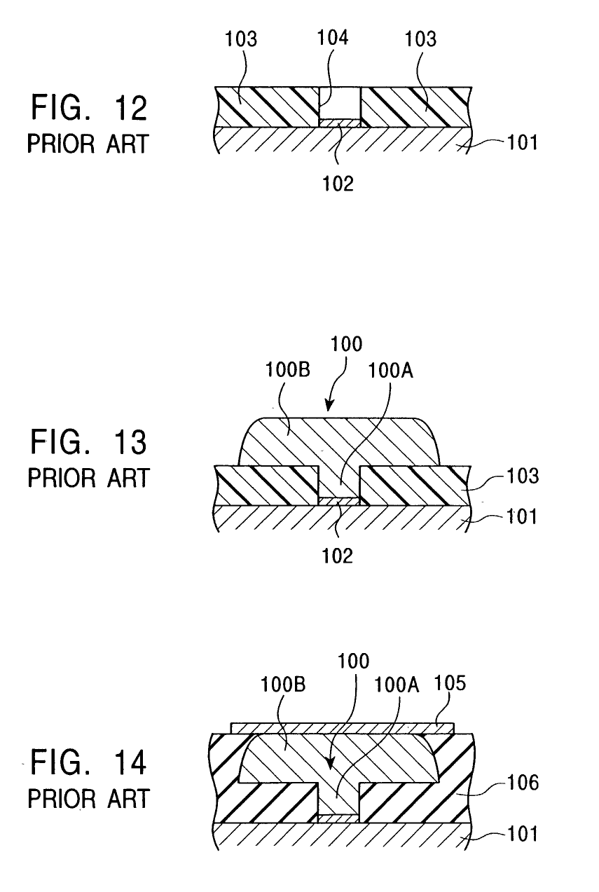

FIG. 9 through FIG. 11 show an embodiment wherein the structure of the terminal electrode in accordance with the present invention has been applied to a thin-film magnetic head. A thin-film magnetic head B according to the embodiment is mounted on the base plate of a rotary cylinder of a VTR apparatus or a magnetic recording apparatus, such as a data storage apparatus.

In the thin-film magnetic head B according to the embodiment, a core incorporating layer 25 is bonded to a side end surface of a plate-like core half 23. One side surface of the core half 23 that has a large area is secured by bonding to the base plate of the rotary cylinder of the foregoing magnetic recording apparatus.

The core half 23 in this embodiment is formed of a ceramic material or ferrite or the like, such as CaTiO₃ or Al₂O₃+TiC, featuring high wear resistance.

One of the surfaces of the core half 23 of the thin-film magnetic head B has been machined to have a long and thin convex curve contour to provide a medium slide surface 26.

The core incorporating layer 25 provided on one surface of the core half 23 includes a write core (inductive head) 30 and a read core (MR core: magnetoresistive core) 31, which have a structure shown in, for example, FIG. 9 through FIG. 11.

As detailedly illustrated in FIG. 9 through FIG. 11, the read core 31 includes a gap layer 33 formed of a nonmagnetic material, such as alumina (Al₂O₃), and provided on a lower shielding layer 32 formed of a magnetic alloy, such as Permalloy (FeNi) or Sendust (Fe—Al—Si alloy). A magnetoresistance effect element is embedded in the gap layer 33. In addition, a gap layer 33′ and an upper shielding layer 34 are deposited on the gap layer 33. The upper shielding layer 34 serves also as a lower core layer of the write core 30 that is provided thereon.

In the write core 30, a gap layer 35 is formed on the upper shielding layer 34 serving also as the lower core layer, and a thin-film coil 36 patterned to be two-dimensionally annular and spiral is formed on the gap layer 35. The thin-film coil 36 is surrounded by an insulating material layer 37. A yoke 38 constructed of an upper core layer formed on the insulating material layer 37 has a magnetic pole distal end 38a thereof exposed to the medium slide surface 26 and opposed against the upper shielding layer 34 serving also as the lower core layer with a minute gap provided therebetween. A proximal end 38b of the yoke 38 is magnetically connected to the upper shielding layer 34 serving also as the lower core layer. The magnetic pole distal end 38a of the yoke 38 is positioned adjacently to the medium slide surface 26, and a magnetic gap WG for writing is provided between the magnetic pole distal end 38a and the distal end of the upper shielding layer 34 adjacent to the medium slide surface 26. A protective layer 39 formed of alumina or the like is provided on the upper core layer 38. Thus, the thin-film magnetic head B is constructed.

The read core 31 includes an electrode layer 41 and a bias layer (not shown) connected to a magnetoresistive element 40 formed of an MR element constituted by a nonmagnetic film sandwiched by a ferromagnetic film and a magnetoresistance effect film, or a spin-valve giant magnetoresistive effect multi-layer film element or the like. When a leakage magnetic field from a magnetic tape acts on a magnetoresistance effect element 20 to which a detection current is being supplied from the electrode layer 41, a change in resistance takes place.

In the read core 31, the electrical resistance of the magnetoresistance effect film changes depending upon the presence of a leakage magnetic field from the magnetic tape. By reading the resistance change, magnetically recorded information can be read from the magnetic tape.

Then, a lead wire 50 pulled out from the outer periphery of the thin-film coil 36 of the write core 30 and a lead wire 51 pulled out from the center of the thin-film coil 36 are extended to an end side of the core incorporating layer 25. At the end side of the core incorporating layer 25, a rectangular electrode pad 52 is connected to the lead wire 50, and a rectangular electrode pad 53 is connected to the lead wire 51. The structure of the terminal electrode 3 described above in conjunction with FIG. 1 is applied to the connection between the lead wire 50 and the electrode pad 52, and the structure of the terminal electrode 3 described above in conjunction with FIG. 1 is applied to the connection between the lead wire 51 and the electrode pad 53.

In the structures according to the embodiment, the lengthwise directions of the lead wires 50 and 51 are orthogonalized with the lengthwise directions of the rectangular electrode pads 52 and 53. Hence, the widths of the lower pads 3A formed on the lead wires 50 and 51 are smaller than the widths in the direction orthogonalized with the lengthwise direction of the electrode pads 52 and 53. In other words, the widths in the direction orthogonalized with the lengthwise direction of the electrode pads 52 and 53 are larger than the widths of the lower pads 3A formed on the lead wires 50 and 51, and the centers of the lower pads 3A formed on the lead wires 50 and 51 are aligned with the centers of the electrode pads 52 and 53 in the direction orthogonalized with the lengthwise directions. The lower pads 3A in this example are shown by chain lines in FIG. 9.

In the structure according to this embodiment also, the operational advantage that can be obtained by the above terminal electrode 3 can be obviously obtained, and the thin-film magnetic head B exhibiting the operational advantage obtained with the above terminal electrode 3 can be obtained.

What is claimed is:

1. A terminal electrode of a thin-film device, the terminal electrode being provided on a lead joint portion of a thin-film device fabricated by a thin-film technology, comprising:
an upper pad; and
a lower pad,
wherein the lower pad is shaped like a pillar projecting from the lead joint portion, and the upper pad, which is wider than the lower pad, is formed on the lower pad such that the center thereof observed at least from one direction is aligned with the center of the lower pad.

2. The terminal electrode of a thin-film device according to claim 1, wherein a lower insulating layer is formed around the lower pad such that it surrounds the lower pad and its front surface is flush with the upper end surface of the lower pad.

3. The terminal electrode of a thin-film device according to claim 1, wherein an upper insulating layer is formed around the upper pad such that it surrounds the upper pad and its front surface is flush with the upper end surface of the upper pad.

4. The terminal electrode of a thin-film device according to claim 1, wherein an electrode pad made of a precious metal is formed on the upper pad such that it covers the upper end surface of the upper pad and is electrically connected to the upper pad, and covers the upper end surface of the upper pad and adheres to the front surface of the upper insulating layer.

5. A thin-film magnetic head comprising the terminal electrode according to claim 1.

6. A manufacturing method for a terminal electrode formed of a lower pad and an upper pad and placed on a lead formed on a substrate, comprising:
a step of applying a resist on the substrate and the lead;
a step of forming a contact hole reaching the lead in the resist;
a step of forming a lower pad made of a conductive material to fill the contact hole;
a step of removing the resist after forming the lower pad;
a step of forming a lower insulating layer around the lower pad;
a step of planarizing the upper surface of the lower insulating layer and the upper surface of the lower pad; and
a step of forming an upper pad on the lower pad.

7. The manufacturing method for a terminal electrode according to claim 6, wherein the lower pad is formed such that the conductive material filling the contact hole is not overflown out of the contact hole, and the upper surface of the lower pad and the upper surface of the lower insulating layer around the lower pad are planarized.

8. The manufacturing method for a terminal electrode according to claim 6, wherein a second contact hole, which is wider than the lower pad, is formed in the resist at a position coaxial with the lower pad after a resist is applied to the planarized upper surfaces of the lower pad and the lower insulating layer, and the second contact hole is filled with a conductive material such that it does not overflow out of the second contact hole, thereby forming the upper pad.

9. The manufacturing method for a terminal electrode according to claim 6, wherein, after the upper pad is formed, an upper insulating layer is formed to surround the upper pad, and an electrode pad made of a precious metal is formed on the upper pad and the upper insulating layer to cover at least the upper pad.

10. The manufacturing method for a terminal electrode according to claim 6, wherein the electrode pad is formed such that it covers the upper surface of the upper pad, is electrically connected to the upper pad, and covers a part of the upper insulating layer around the upper pad.
